(19) United States
(12) Patent Application Publication
(10) Pub. No.: US 2009/0122504 A1
(43) Pub. Date: May 14, 2009

(54) ELECTRONIC DEVICE CAPABLE OF DISPLAYING DIGITAL IMAGE INFORMATION ON A REMOVABLE SHEET OF ELECTRONIC PAPER

(75) Inventor: Shao-Ming LEE, Nan-Tou Hsien (TW)

Correspondence Address: MCNEES WALLACE & NURICK LLC, 100 PINE STREET, P.O. BOX 1166, HARRISBURG, PA, 17108-1166, US

(73) Assignee: UNIVERSAL SCIENTIFIC INDUSTRIAL CO., LTD., Nan-Tou Hsien (TW)

(21) Appl. No.: 12/058,079

(22) Filed: Mar. 28, 2008

(30) Foreign Application Priority Data
Nov. 8, 2007 (TW) 096142204

(51) Int. Cl. H05K 5/02

(52) U.S. Cl. 361/809

(57) ABSTRACT

An electronic device includes a housing having a side surface formed with a receiving groove, a driving electrode layer mounted fixedly in the receiving groove and including a plurality of electrodes, a control module disposed in the housing, connected electrically to the driving electrode layer, and operable so as to apply respectively a plurality of driving voltages corresponding to digital image information to the electrodes of the driving electrode layer, and a sheet of electronic paper disposed removably in the receiving groove in the housing and over the driving electrode layer for displaying the digital image information thereon in response to application of the driving voltages by the control module.

### BACKGROUND OF THE INVENTION

1. Field of the Invention

The invention relates to an electronic paper display device, more particularly to an electronic device capable of displaying digital image information on a sheet of electronic paper.

2. Description of the Related Art

Referring to FIG. 1, a conventional electronic paper display 1 is shown to include a closed transparent film layer 11 configured with an inner space that is filled with a plurality of microcapsules 12 therein, and an electrode layer 13 attached fixedly to a bottom surface of the transparent film layer 11. For each microcapsule 12, a solvent 121 is hermetically encapsulated, and a plurality of white particles 123 having a positively charged polarity, and a plurality of black particles 122 having a negatively charged polarity float in the solvent 121 in a dispersed manner.

In use, the conventional electronic paper display 1 is generally controlled by a control chip 14 to display digital image information thereon by applying respectively a plurality of driving voltages corresponding to the digital image information to electrodes of the electrode layer 13.

Referring to FIG. 2, a conventional electronic device, such as an electronic book 2, is shown to employ the conventional electronic paper display 1 as a display. Since the conventional electronic paper display 1 is incorporated with the electrode layer 13, and is installed fixedly in a housing of the conventional electronic book 2, the conventional electronic paper display 1 cannot be a removable hard copy, thereby resulting in inconvenience during use.

### SUMMARY OF THE INVENTION

Therefore, the object of the present invention is to provide an electronic device that can display digital image information on a removable sheet of electronic paper.

According to the present invention, an electronic device comprises:
a housing having a side surface formed with a receiving groove;

a driving electrode layer mounted fixedly in the receiving groove and including a plurality of electrodes;

a control module disposed in the housing, connected electrically to the driving electrode layer, and operable so as to apply respectively a plurality of driving voltages corresponding to digital image information to the electrodes of the driving electrode layer; and

a sheet of electronic paper disposed removably in the receiving groove in the housing and over the driving electrode layer for displaying the digital image information thereon in response to application of the driving voltages by the control module.

### BRIEF DESCRIPTION OF THE DRAWINGS

Other features and advantages of the present invention will become apparent in the following detailed description of the preferred embodiments with reference to the accompanying drawings, of which:

FIG. 1 is a schematic sectional view of a conventional electronic paper display;

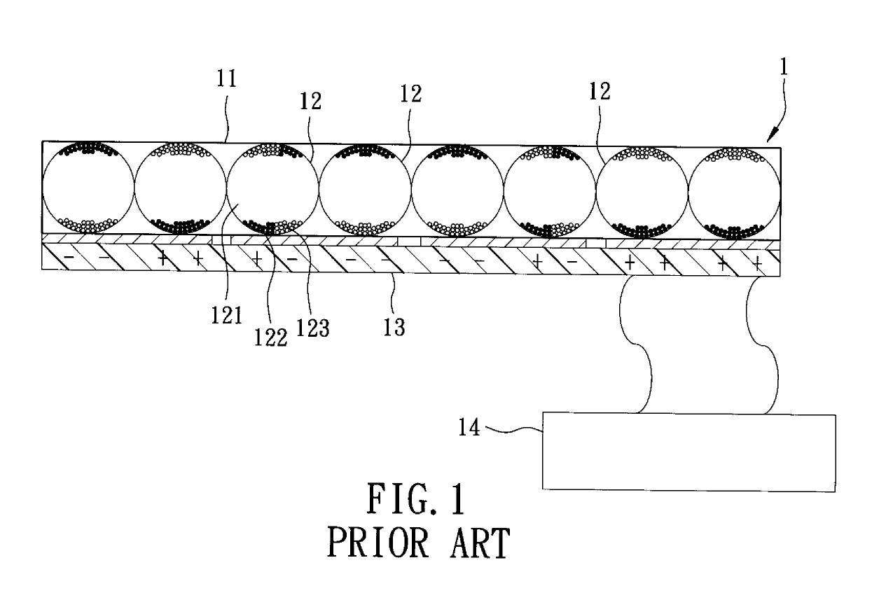

FIG. 2 is a schematic view of a conventional electronic device employing the conventional electronic paper display;

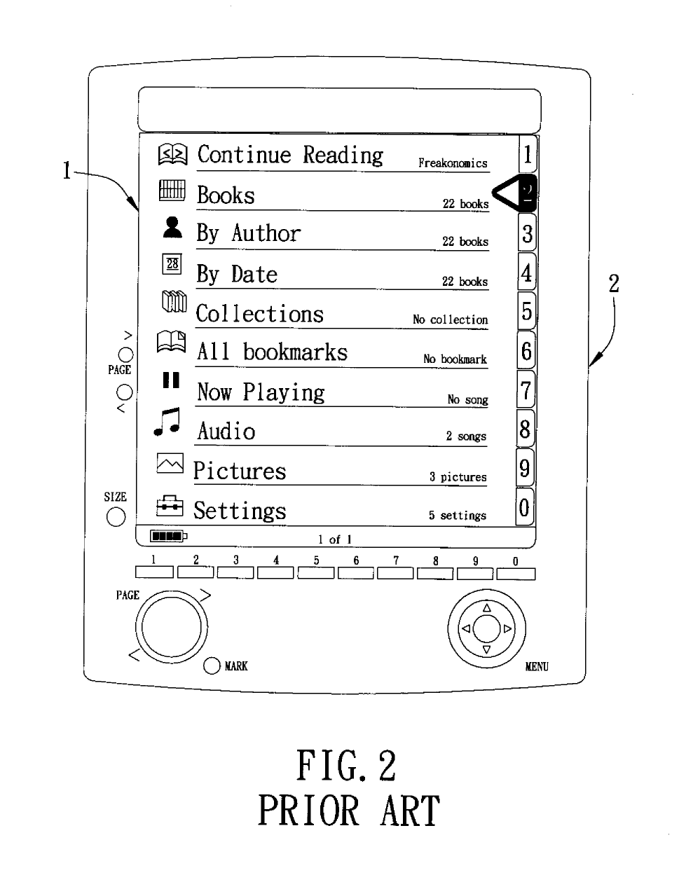

FIG. 3 is a partly exploded perspective view showing the first preferred embodiment of an electronic device according to the present invention;

FIG. 4 is a fragmentary enlarged schematic view showing a sheet of electronic paper of the first preferred embodiment;

FIG. 5 is an assembled perspective view showing the first preferred embodiment;

FIG. 6 is a fragmentary schematic sectional view showing the first preferred embodiment when a transparent cover is pivoted to an open position;

FIG. 7 is a fragmentary schematic sectional view showing the first preferred embodiment;

FIG. 8 is a partly exploded perspective view showing the second preferred embodiment of an electronic device according to the present invention; and

FIG. 9 is a fragmentary schematic sectional view showing the second preferred embodiment.

### DETAILED DESCRIPTION OF THE PREFERRED EMBODIMENTS

Before the present invention is described in greater detail, it should be noted that like elements are denoted by the same reference numerals throughout the disclosure.

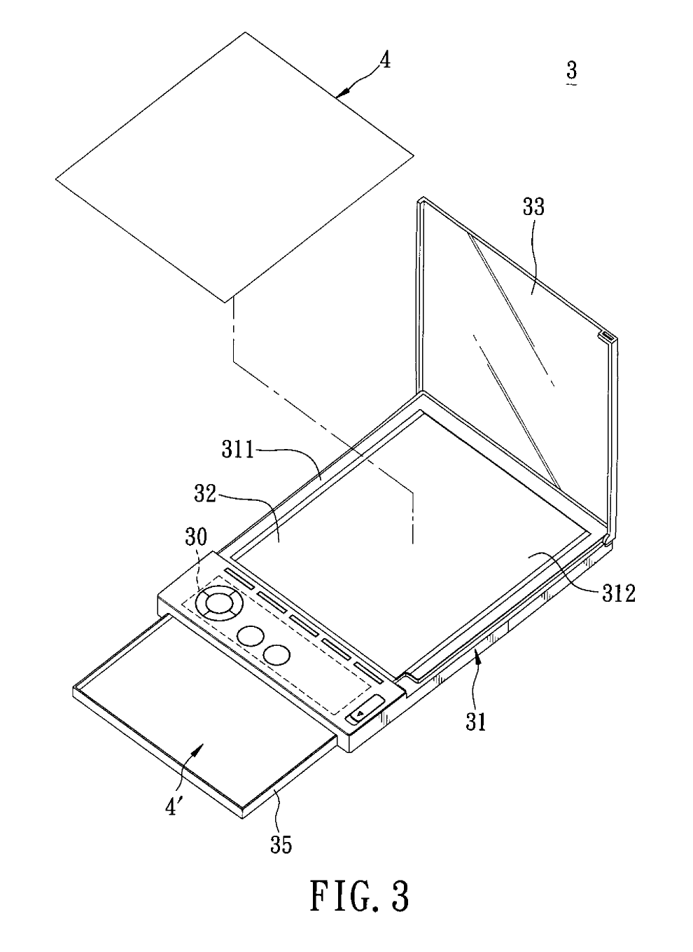

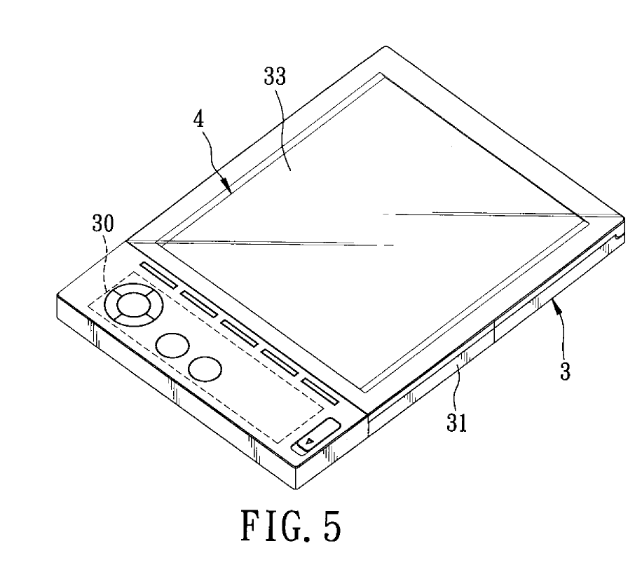

Referring to FIGS. 3, 5, 6 and 7, the first preferred embodiment of an electronic device 3 according to the present invention is shown to include a housing 31, a driving electrode layer 32, a control module 30, and a sheet of electronic paper 4. In this embodiment, the electronic device 3 is an electronic book. However, in other embodiments, the electronic device 3 can be a personal digital assistant, a notebook computer or a mobile phone.

The housing 31 has a side surface 311 formed with a receiving groove 312.

The driving electrode layer 32 is mounted fixedly in the receiving groove 312, and includes a plurality of electrodes.

The control module 30 is disposed in the housing 31, is connected electrically to the driving electrode layer 32, and is operable so as to apply respectively a plurality of driving voltages corresponding to digital image information to the electrodes of the driving electrode layer 32.

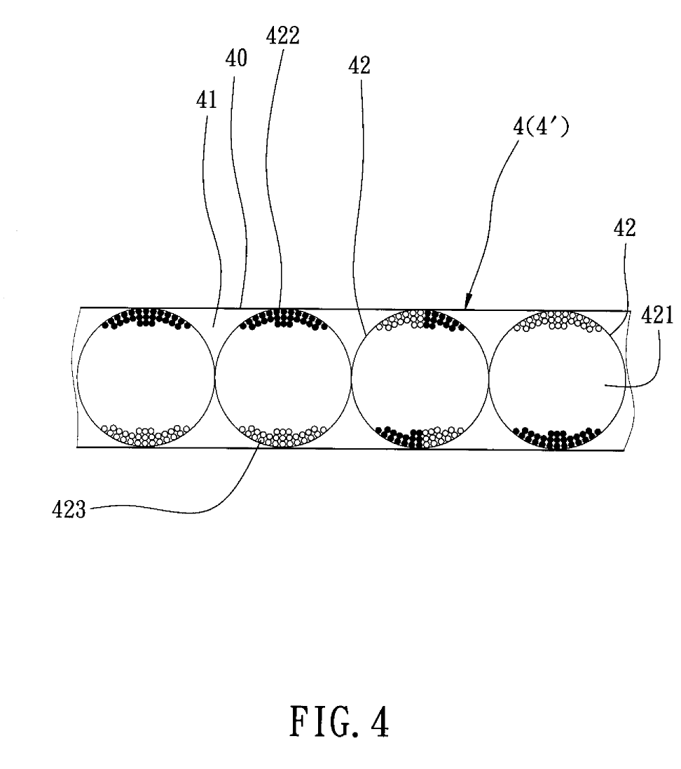

The sheet of electronic paper 4 is disposed removably in the receiving groove 312 in the housing 31 and over the driving electrode layer 32 for displaying the digital image information thereon in response to application of the driving voltages by the control module 30. In this embodiment, referring further to FIG. 4, the sheet of electronic paper 4 includes a closed transparent film layer 40 configured with an inner space 41, and a plurality of microcapsules 42 filled in the inner space 41 in the transparent film layer 40 and serving as so-called electronic ink. For each microcapsule 42, a solvent 421 is hermetically encapsulated, and a plurality of white particles 423 each having a positively charged polarity, and a plurality of black particles 422 each having a negatively charged polarity float in the solvent 421 in a dispersed manner. It is noted that the sheet of electronic paper 4 has bistable characteristics. Thus, the digital image information displayed on the sheet of electronic paper 4 can be maintained when the sheet of electronic paper 4 is removed from the housing 31.

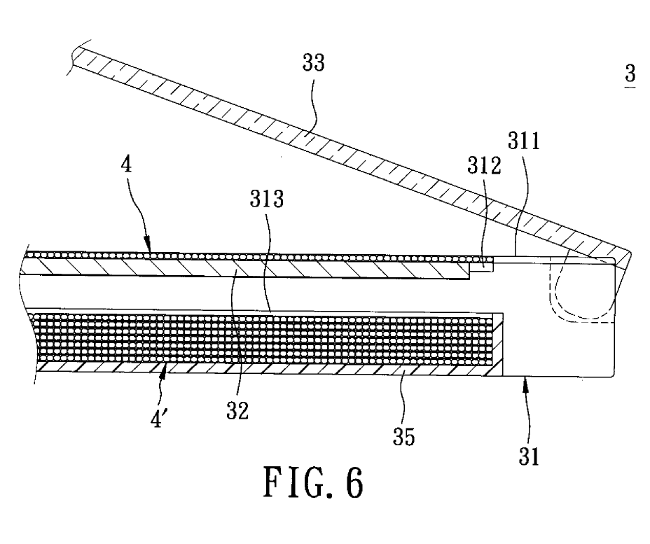

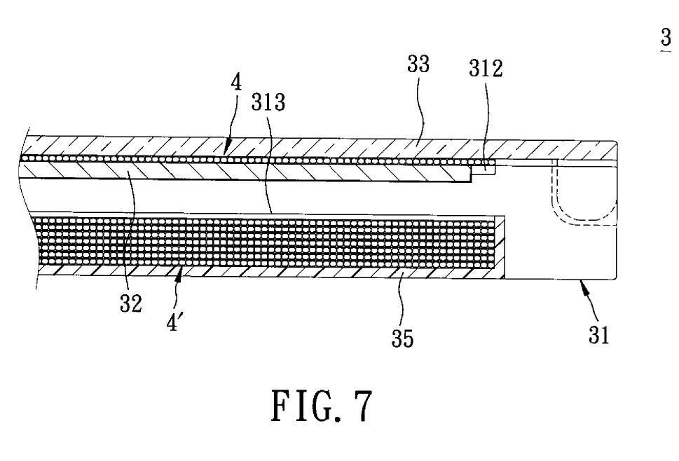

In this embodiment, the electronic device 3 further includes a transparent cover 33 connected pivotally to the housing 31 for covering the receiving groove 312 in the housing 31 such that the sheet of electronic paper 4 is positioned between the transparent cover 33 and the driving electrode layer 32 when the transparent cover 33 is at a closed position, as shown in FIG. 7. When the transparent cover 33 is pivoted away from the housing 31 to an open position, the sheet of electronic paper 4 is removable from the receiving groove 312 in the housing 31, as shown in FIG. 6.

The housing 31 is further formed with an inner accommodating space 313 adapted for accommodating a plurality of backup sheets of electronic paper 4′. In this embodiment, the backup sheets of electronic paper 4′ have the same configuration as that of the sheet of electronic paper 4, and are placed in a drawer 35 inserted detachably into the inner accommodating space 313.

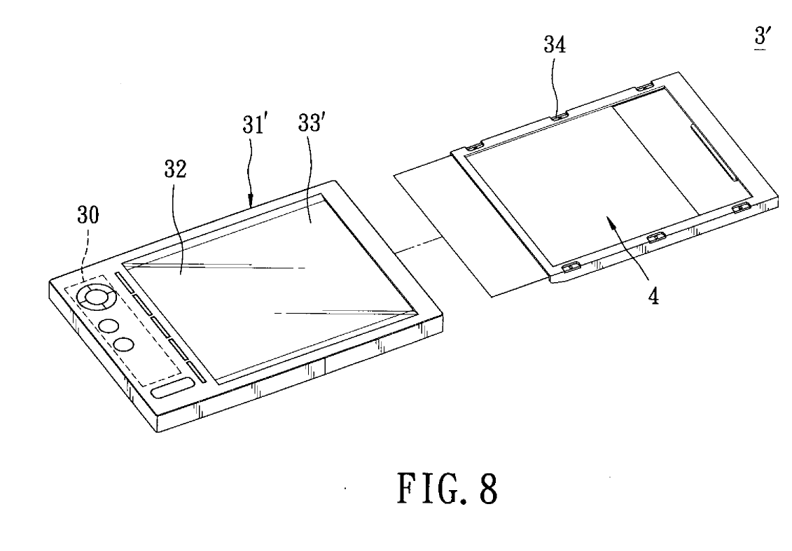

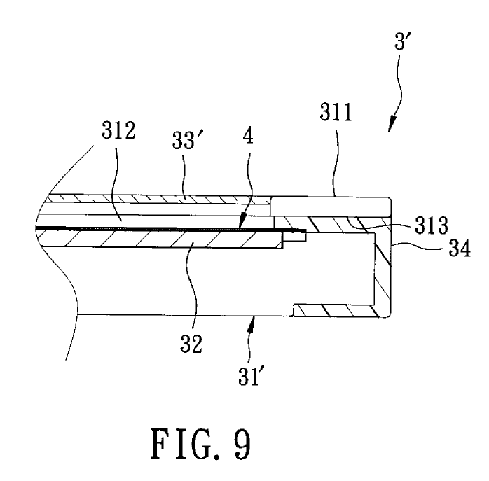

FIGS. 8 and 9 illustrate the second preferred embodiment of an electronic device 3′ according to this invention, which is a modification of the first preferred embodiment. In this embodiment, the housing 31′ further has an insertion slot 313 in spatial communication with the receiving groove 312 in the side surface 311 of the housing 31′. The electronic device 3′ further includes a transparent plate 33′, and a paper-mounting frame 34.

The transparent plate 33′ is used as a substitute for the transparent cover 33 of the first preferred embodiment, is mounted fixedly on the side surface 311 of the housing 31′, is spaced apart from the driving electrode layer 32, and covers the receiving groove 312 in the housing 31′.

The paper-mounting frame 34 is mounted detachably with the sheet of electronic paper 4 thereon. An assembly of the paper-mounting frame 34 and the sheet of electronic paper 4 is inserted detachably into the receiving groove 312 in the housing 31′ via the insertion slot 313 such that the sheet of electronic paper 4 is disposed over the driving electrode layer 32 and between the transparent plate 33′ and the driving electrode layer 32.

In sum, after the sheet of electronic paper 4 is removed from the housing 31, 31′, it can be used as a hard copy, thereby resulting in convenience during use.

While the present invention has been described in connection with what are considered the most practical and preferred embodiments, it is understood that this invention is not limited to the disclosed embodiments but is intended to cover various arrangements included within the spirit and scope of the broadest interpretation so as to encompass all such modifications and equivalent arrangements.

I claim:

1. An electronic device comprising:
a housing having a side surface formed with a receiving groove;
a driving electrode layer mounted fixedly in said receiving groove and including a plurality of electrodes;
a control module disposed in said housing, connected electrically to said driving electrode layer, and operable so as to apply respectively a plurality of driving voltages corresponding to digital image information to said electrodes of said driving electrode layer; and
a sheet of electronic paper disposed removably in said receiving groove in said housing and over said driving electrode layer for displaying the digital image information thereon in response to application of the driving voltages by said control module.

2. The electronic device as claimed in claim 1, wherein said sheet of electronic paper includes a closed transparent film layer configured with an inner space, and a plurality of microcapsules filled in said inner space in said transparent film layer.

3. The electronic device as claimed in claim 1, further comprising a transparent cover connected pivotally to said housing for covering said receiving groove in said housing such that said sheet of electronic paper is removable from said receiving groove in said housing when said transparent cover is pivoted away from said housing.

4. The electronic device as claimed in claim 1, wherein said housing further has an insertion slot in spatial communication with said receiving groove, said electronic device further comprising:
a transparent plate mounted fixedly on said side surface of said housing, spaced apart from said driving electrode layer and covering said receiving groove in said housing; and
a paper-mounting frame mounted detachably with said sheet of electronic paper thereon, an assembly of said paper-mounting frame and said sheet of electronic paper being inserted detachably into said receiving groove in said housing via said insertion slot such that said sheet of electronic paper is disposed over said driving electrode layer and between said transparent plate and said driving electrode layer.

5. The electronic device as claimed in claim 1, wherein said housing is further formed with an inner accommodating space adapted for accommodating a backup sheet of electronic paper.
